(19) United States
(12) Patent Application Publication
(10) Pub. No.: US 2008/0042524 A1
(43) Pub. Date: Feb. 21, 2008

(54) FILM BULK ACOUSTIC RESONATOR AND METHOD FOR MANUFACTURING

(75) Inventor: Hironobu SHIBATA, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/767,688

(22) Filed: Jun. 25, 2007

(30) Foreign Application Priority Data
Jun. 29, 2006 (JP) 2006-179109

(51) Int. Cl. H01L 41/00; H01L 41/22

(52) U.S. Cl. 310/348; 29/25.35

(57) ABSTRACT

A film bulk acoustic resonator includes: a support body having a lower hollow portion; a lower electrode supported on the support body and provided above the lower hollow portion; a piezoelectric layer provided on the lower electrode; an upper electrode provided on the piezoelectric layer; a sidewall surrounding the upper electrode; an upper sealing body bonded to an upper end of the sidewall and defining an upper hollow portion along with the sidewall; and a relay electrode. A portion of the sidewall is composed of the piezoelectric layer. The relay electrode is provided on the support body below the portion of the sidewall constituting the piezoelectric layer for extracting the lower electrode and the upper electrode onto the support body outside the sidewall.

### CROSS-REFERENCE TO RELATED APPLICATION

This application is based upon and claims the benefit of priority from the prior Japanese Patent Application No. 2006-179109, filed on Jun. 29, 2006; the entire contents of which are incorporated herein by reference.

### BACKGROUND OF THE INVENTION

1. Field of the Invention

This invention relates to a film bulk acoustic resonator with a piezoelectric layer sandwiched between an upper and lower electrode.

2. Background Art

A film bulk acoustic resonator needs a hollow structure above and below its resonator portion so as not to prevent the mechanical vibration of the resonator portion. For example, in a structure disclosed in JP 2005-304021A, a first electrode, a piezoelectric layer, and a second electrode are provided sequentially from bottom on a silicon wafer having a cavity. The structure further includes a hollow portion provided around and above the second electrode and defined by a peripheral wall and a cap.

In order to connect the first and second electrode to an external circuit, these electrodes need to be extracted outside the hollow portion. In JP 2005-304021A, a lead is formed between the piezoelectric layer and the lower end of the peripheral wall, and a via filled with conductive material and passing through the thickness of the peripheral wall is connected to the lead. That is, the first and second electrode are extracted to the upper face of the cap. In this structure, a via must be formed in the peripheral wall. This is a more complex process than the process of patterning an interconnect on the wafer. In addition, JP 2005-304021A does not disclose how to connect the first electrode formed below the piezoelectric layer to the lead formed above the piezoelectric layer.

### SUMMARY OF THE INVENTION

According to an aspect of the invention, there is provided a film bulk acoustic resonator including: a support body having a lower hollow portion; a lower electrode supported on the support body and provided above the lower hollow portion; a piezoelectric layer provided on the lower electrode; an upper electrode provided on the piezoelectric layer; a sidewall surrounding the upper electrode, a portion of the sidewall being composed of the piezoelectric layer; an upper sealing body bonded to an upper end of the sidewall and defining an upper hollow portion along with the sidewall; and a relay electrode provided on the support body below the portion of the sidewall constituting the piezoelectric layer for extracting the lower electrode and the upper electrode onto the support body outside the sidewall.

According to other aspect of the invention, there is provided a method for manufacturing a film bulk acoustic resonator including: forming a lower electrode and a relay electrode on a support body; forming a piezoelectric layer so as to cover the lower electrode and the relay electrode; forming an upper electrode on the piezoelectric layer; forming a sidewall surrounding the upper electrode, a portion of the sidewall being composed of the piezoelectric layer; forming an extraction electrode provided in contact with the relay electrode for extracting the lower electrode and the upper electrode onto the support body outside the sidewall; bonding an upper sealing body to an upper end of the sidewall, the upper sealing body defining an upper hollow portion along with the sidewall; and forming a lower hollow portion below the lower electrode.

### BRIEF DESCRIPTION OF THE DRAWINGS

FIG. 1 is a schematic view illustrating the cross-sectional structure of the main part of a film bulk acoustic resonator according to a first embodiment of the invention.

FIG. 2 is a cross-sectional view taken along line A-A in FIG. 1.

FIGS. 3 to 8 are schematic views illustrating the main part of a process for manufacturing a film bulk acoustic resonator according to the first embodiment.

FIGS. 9 to 11 are schematic views illustrating another example process for manufacturing a film bulk acoustic resonator.

FIG. 12 is a schematic view illustrating the cross-sectional structure of the main part of a film bulk acoustic resonator according to a second embodiment of the invention.

FIG. 13 is a schematic view illustrating the main part of a process for manufacturing a film bulk acoustic resonator according to the second embodiment.

### DETAILED DESCRIPTION OF THE INVENTION

Embodiments of the invention will now be described with reference to the drawings, where like elements are marked with like reference numerals.

### First Embodiment

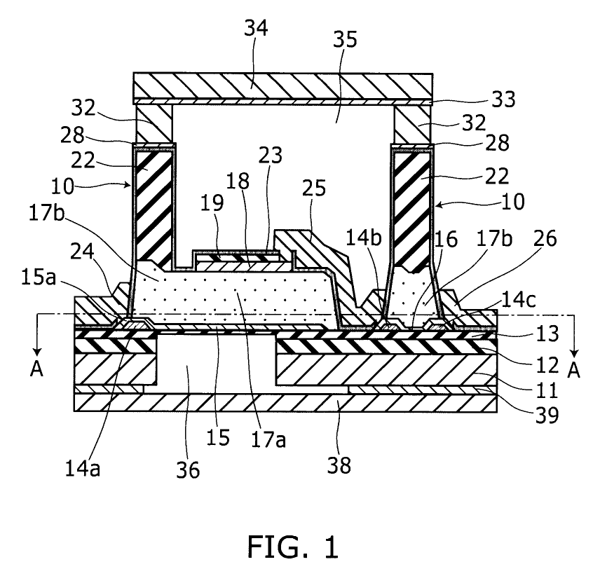

FIG. 1 is a schematic view illustrating the cross-sectional structure of the main part of a film bulk acoustic resonator according to a first embodiment of the invention.

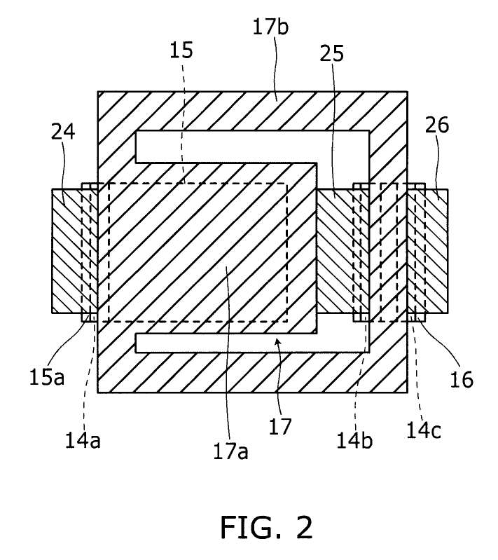

FIG. 2 is a cross-sectional view taken along line A-A in FIG. 1.

On a support body having a lower hollow portion 36, a resonator portion (device portion) with a piezoelectric layer 17a sandwiched between a lower electrode 15 and an upper electrode 18 is provided. The support body is illustratively made of a high-resistance silicon substrate 11. A thermal oxide film 12 and a silicon nitride film 13 are sequentially formed on the frontside of the high-resistance silicon substrate 11. A lower sealing body 38, also made of high-resistance silicon, is stuck to the backside of the high-resistance silicon substrate 11.

The lower electrode 15 is supported on the support body and provided above the lower hollow portion 36. The piezoelectric layer 17a is provided on the lower electrode 15, and the upper electrode 18 is provided on the piezoelectric layer 17a. On the upper electrode 18 is formed a mass addition film 19 for adjusting the mass of the resonator portion to a desired value to set the resonance frequency to a desired value.

As shown in FIG. 2, the piezoelectric layer 17a serving as a resonator portion is surrounded by a peripheral portion 17b, which is formed in the same process and made of the same material as the piezoelectric layer 17a. Relay electrodes 15a, 16 are formed on the support body below the peripheral portion 17b. An insulator layer 22 illustratively made of silicon oxide film is formed on the peripheral portion 17b. An upper sealing body 34 illustratively made of silicon is bonded to the upper end of the insulator layer 22 via bonding metal layers 32, 33 to form an upper hollow portion 35. An upper electrode 18 is provided inside the upper hollow portion 35.

In the film bulk acoustic resonator according to this embodiment, the upper hollow portion 35 and the lower hollow portion 36 provided above and below the resonator portion (the portion with the piezoelectric layer 17a sandwiched between the upper electrode 18 and the lower electrode 19) allow the resonator portion to be subjected to mechanical vibration in its thickness direction.

Furthermore, a sidewall 10, which defines the upper hollow portion 35 together with the upper sealing body 34, is composed of the piezoelectric layer peripheral portion 17b, the insulator layer 22, and the bonding metal layers 32, 33 sequentially from bottom. That is, the piezoelectric layer originally serving as a resonator portion is also used as part of the sidewall 10 for forming the upper hollow portion 35. Thus the process for forming the resonator portion can be partially shared with the process for forming the sidewall. This can increase the process efficiency and achieve cost reduction.

The lower electrode 15 is connected to the relay electrode 15a provided below the piezoelectric layer peripheral portion 17b constituting part of the sidewall 10. The relay electrode 15a is connected to a lower extraction electrode 24 provided on the support body outside the sidewall 10. That is, the lower electrode 15 provided inside the sidewall 10 is extracted outside the sidewall 10 through the relay electrode 15a and the lower extraction electrode 24, and is connectable to an external circuit.

The upper electrode 18 is connected to the relay electrode 16 provided below the piezoelectric layer peripheral portion 17b through an inner upper extraction electrode 25. The relay electrode 16 is connected to an outer upper extraction electrode 26 provided on the support body outside the sidewall 10. That is, the upper electrode 18 provided inside the sidewall 10 is extracted outside the sidewall 10 through the inner upper extraction electrode 25, the relay electrode 16, and the outer upper extraction electrode 26, and is connectable to an external circuit.

The relay electrodes 15a, 16 for externally extracting the upper and lower electrode are patterned on the support body simultaneously with the formation of the lower electrode 15 before the piezoelectric layer 17a, 17b is formed. Thus the process for forming the resonator portion can be partially shared with the process for forming the external extraction electrodes. This can increase the process efficiency and achieve cost reduction. Furthermore, the external extraction structure can be formed by the known technique for patterning an interconnect on a semiconductor wafer without the process as in JP 2005-304021A where a via is formed in the wall of the upper hollow portion and filled with conductive material. This also contributes to reducing the process cost.

The piezoelectric layer peripheral portion 17b and the insulator layer 22 provided on the relay electrodes 15a, 16 are electrically insulative. Hence no short circuit occurs between the upper electrode 18 and the lower electrode 15. Furthermore, the insulator layer 22 illustratively made of silicon oxide, which has a smaller relative dielectric constant than materials commonly used for a piezoelectric layer (e.g. aluminum nitride), can be formed thicker than the piezoelectric layer peripheral portion 17b. Thus the increase of parasite capacitance between the bonding metal layers 32, 33 and the relay electrodes 15a, 16 can be reduced.

The material of the sidewall 10 is free from resin. The surface of the insulator layer 22 and the piezoelectric layer 17a, 17b facing the upper hollow portion 35 is covered with a protective film 23 illustratively made of silicon nitride. Hence no decomposition or shattering of resin components occurs in high-temperature, high-pressure, and high-humidity environments. Thus there is no decrease of the resonance frequency or degradation of resonance characteristics due to shattered material attached to the resonator portion, and a highly reliable hollow structure can be achieved.

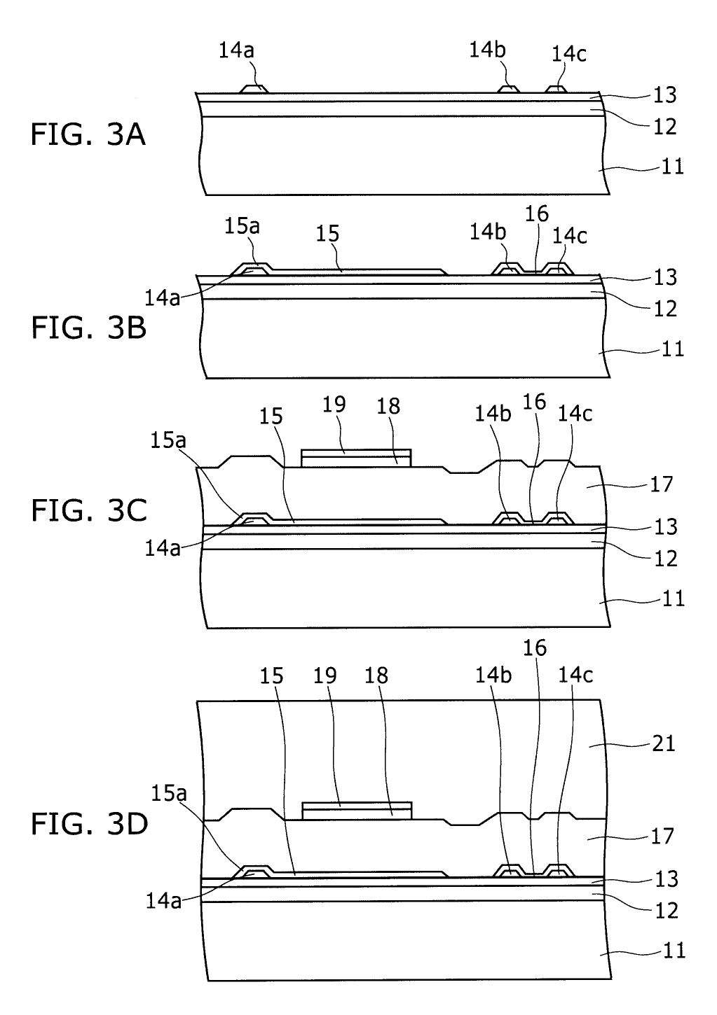

FIGS. 3 to 8 are schematic views illustrating the main part of a process for manufacturing a film bulk acoustic resonator according to the first embodiment.

First, as shown in FIG. 3A, a thermal oxide film 12 is formed on the major surface of a high-resistance silicon substrate 11. On the thermal oxide film 12, a silicon nitride film 13 thinner than the thermal oxide film 12 is formed by thermal CVD (Chemical Vapor Deposition), for example.

Foundation electrodes 14a to 14c are selectively formed on the silicon nitride film 13. As shown in FIG. 2, the foundation electrodes 14a to 14c are formed in a striped configuration. The foundation electrodes 14a to 14c serve as an etching stopper for etching a piezoelectric layer 17 described later. Here, if the relay electrodes 15a, 16 themselves have a high etching selection ratio relative to the piezoelectric layer 17, the foundation electrodes 14a to 14c are not necessarily needed. All edges of the foundation electrodes 14a to 14c are preferably tapered for improving the step coverage of the relay electrodes 15a, 16 formed thereon.

Next, as shown in FIG. 3B, a lower electrode 15 is formed on the silicon nitride film 13. The lower electrode 15 is formed on a portion of the silicon nitride film 13 which is to be a resonator portion. The relay electrode 15a, which is one end of the lower electrode 15, covers the foundation electrode 14a. The relay electrode 15a covering the foundation electrode 14a serves as a relay electrode for extracting the lower electrode 15 outside the sidewall 10 (see FIG. 1). Furthermore, on the silicon nitride film 13, a relay electrode 16 for extracting an upper electrode 19 (see FIG. 1) outside the sidewall 10 is formed so as to cover the foundation electrodes 14b, 14c.

The lower electrode 15 and the relay electrodes 15a, 16 are produced by selectively etching a conductive film formed entirely on the silicon nitride film 13. That is, the lower electrode 15 and the relay electrodes 15a, 16 can be simultaneously formed, and the process cost can be reduced.

The lower electrode 15 and the relay electrodes 15a, 16 can be made of tungsten, molybdenum, titanium, aluminum, ruthenium, rhodium, palladium, iridium, or platinum, for example.

Next, as shown in FIG. 3C, a piezoelectric layer 17 is formed on the silicon nitride film 13 so as to cover the lower electrode 15 and the relay electrodes 15a, 16. The piezoelectric layer 17 can be made of aluminum nitride (AlN), zinc oxide (ZnO), zirconate titanate (PZT), or barium titanate (BaTiO₃), for example.

An upper electrode 18 is formed on the piezoelectric layer 17, and a mass addition film 19 is formed on the upper electrode 18. The upper electrode 18 can be made of tungsten, molybdenum, titanium, aluminum, ruthenium, rhodium, palladium, iridium, or platinum, for example. The mass addition film 19 can be made of insulating material such as silicon nitride (SiN) or metal material such as aluminum and molybdenum, for example. In the upper electrode 18 and the mass addition film 19, the portion other than the resonator portion is etched away.

Next, as shown in FIG. 3D, a silicon oxide film 21 is formed on the piezoelectric layer 17 by plasma CVD, for example, so as to cover the upper electrode 18 and the mass addition film 19. Then the silicon oxide film 21 is planarized by the resist etch back or CMP process. After the planarization, the silicon oxide film 21 has a thickness of 0.3 μm or more, for example.

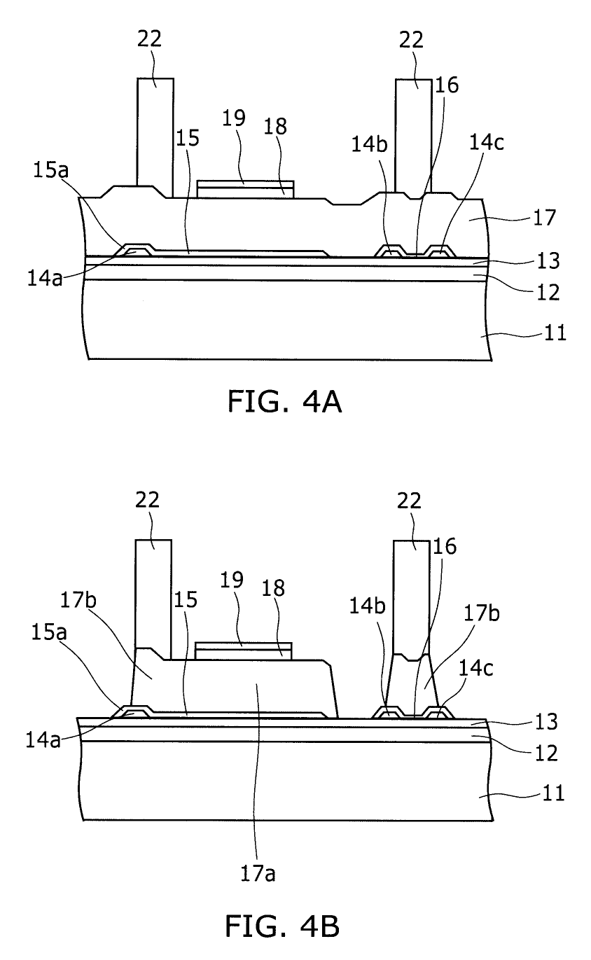

Next, as shown in FIG. 4A, the silicon oxide film 21 is selectively etched to form an insulator layer 22 spaced apart from and surrounding the upper electrode 18 on all four sides. In forming the insulator layer 22, the silicon oxide film 21 is first etched by RIE (Reactive Ion Etching), and then by wet etching with a chemical solution that does not corrode the mass addition film 19, the upper electrode 18, and the piezoelectric layer 17. This prevents the mass addition film 19, the upper electrode 18, and the piezoelectric layer 17 constituting the resonating portion from being thinned by RIE and its mass from being varied. Thus variation of the resonance frequency from its design value can be prevented. The insulator layer 22 serves as part of the sidewall 10 for forming an upper hollow portion 35.

Next, as shown in FIG. 4B, the piezoelectric layer 17 is selectively etched away using an etching mask, not shown. As shown in FIG. 2, the piezoelectric layer 17 is left unremoved not only in the resonator portion (the portion sandwiched between the lower electrode 15 and the upper electrode 18) 17a, but also in the peripheral portion 17b surrounding the resonator portion 17a on all four sides. The peripheral portion 17b serves as part of the sidewall 10 for forming the upper hollow portion 35. Thus, because part of the sidewall 10 is also formed simultaneously with the process for forming the resonator portion, cost reduction is achieved by commonality of processes.

Even if the relay electrodes 15a, 16 are excessively removed during etching the piezoelectric layer 17, the underlying foundation electrodes 14a to 14c can be reliably left because the foundation electrodes 14a to 14c are made of material having a higher etching selection ratio relative to the piezoelectric layer 17 than the relay electrodes 15a, 16. The foundation electrodes 14a to 14c serve as part of the relay electrodes, and the lower electrode and the upper electrode can be reliably extracted outside the sidewall. When the foundation electrodes 14a to 14c having a high etching selection ratio are provided, materials having lower resistance can be selected for the relay electrodes 15a, 16, giving priority to electrical characteristics.

By selective removal of the piezoelectric layer 17, part of the relay electrode 15a and part of the relay electrode 16 are exposed. In the relay electrode 15a, the portion outside the region surrounded by the insulator layer 22 and the piezoelectric layer peripheral portion 17b is exposed. In the relay electrode 16, the portion other than below the piezoelectric layer peripheral portion 17b, that is, the portion outside and inside the region surrounded by the insulator layer 22 and the piezoelectric layer peripheral portion 17b is exposed.

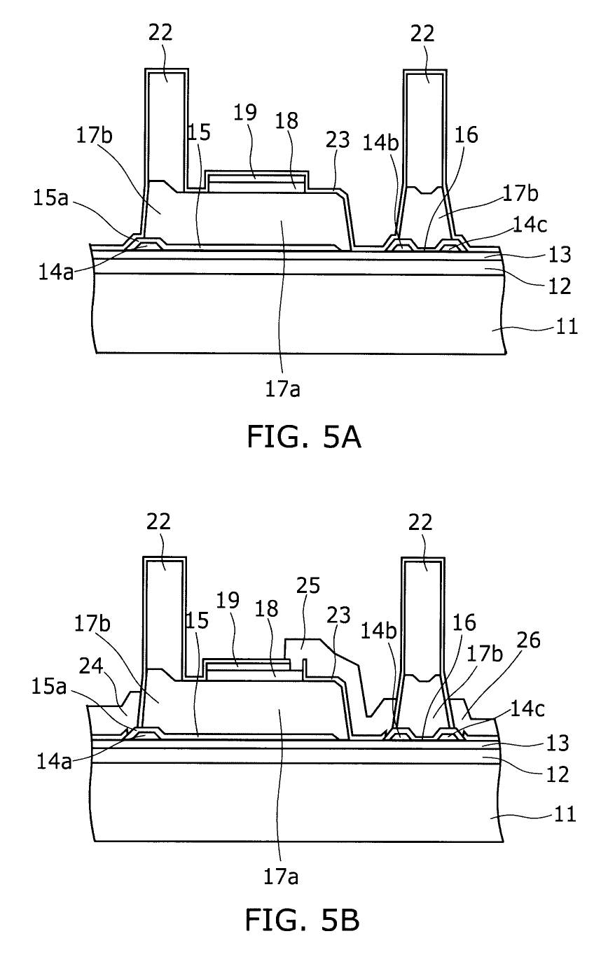

Next, as shown in FIG. 5A, a protective film 23 is formed to cover all the exposed surface of the structure produced by the foregoing processes. The protective film 23 is a silicon nitride film formed by plasma CVD, for example. Alternatively, the protective film 23 can be made of aluminum nitride (AlN) or nitrogen-doped silicon carbide (SiCN). The protective film 23 has a thickness of about several hundred angstroms, for example.

Next, as shown in FIG. 5B, the protective film 23 is partially removed to expose part of the relay electrodes 15a, 16. In the relay electrode 15a, the portion outside the region surrounded by the insulator layer 22 and the piezoelectric layer peripheral portion 17b is exposed. In the relay electrode 16, the portion other than below the piezoelectric layer peripheral portion 17b, that is, the portion outside and inside the region surrounded by the insulator layer 22 and the piezoelectric layer peripheral portion 17b is exposed. Along with the protective film 23, the underlying mass addition film 19 is also partially removed, and the upper electrode 18 is also partially exposed.

Then a lower extraction electrode 24 is formed in contact with the exposed portion of the relay electrode 15a outside the region surrounded by the insulator layer 22 and the piezoelectric layer peripheral portion 17b. An inner upper extraction electrode 25 is formed in contact with the exposed portion of the upper electrode 18 and the exposed portion of the relay electrode 16 inside the region surrounded by the insulator layer 22 and the piezoelectric layer peripheral portion 17b. Furthermore, an outer upper extraction electrode 26 is formed in contact with the exposed portion of the relay electrode 16 outside the region surrounded by the insulator layer 22 and the piezoelectric layer peripheral portion 17b. The lower extraction electrode 24, the inner upper extraction electrode 25, and the outer upper extraction electrode 26 are produced by, for example, depositing aluminum film to about 1 μm followed by selective wet etching.

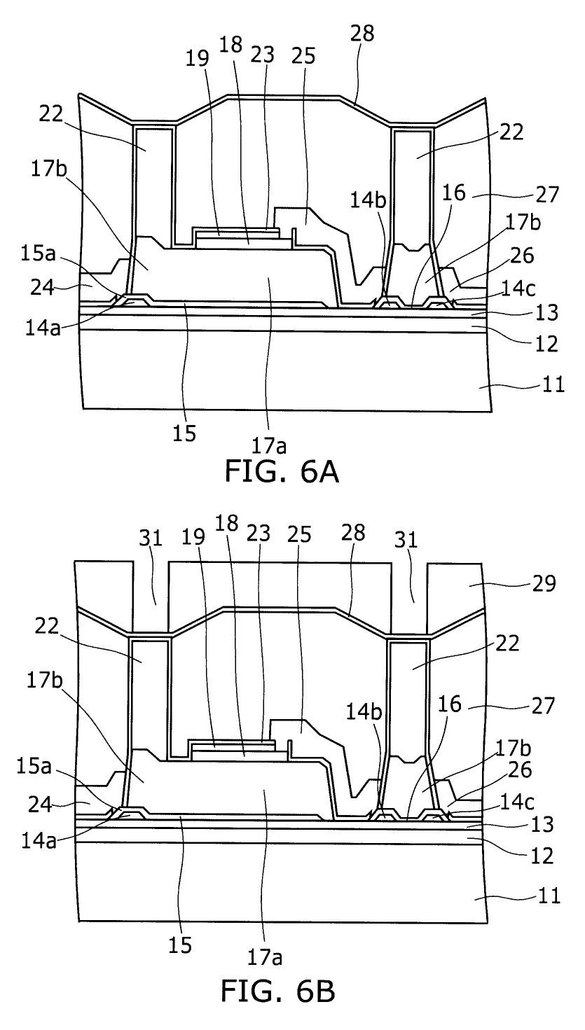

Next, as shown in FIG. 6A, a protective resist layer 27 is applied to a height comparable to that of the insulator layer 22. Then the protective resist layer 27 on the insulator layer 22 is selectively removed, and a feeder metal film 28 is formed on the protective resist layer 27 and the insulator layer 22. The feeder metal film 28 is illustratively made of a Ti (titanium) film and a Pd (palladium) film formed thereon.

As shown in FIG. 6B, a plating resist 29 is formed on the feeder metal film 28. In the plating resist 29, an opening 31 is formed at the portion above the insulator layer 22. The width of the opening 31 is slightly smaller than the width of the insulator layer 22.

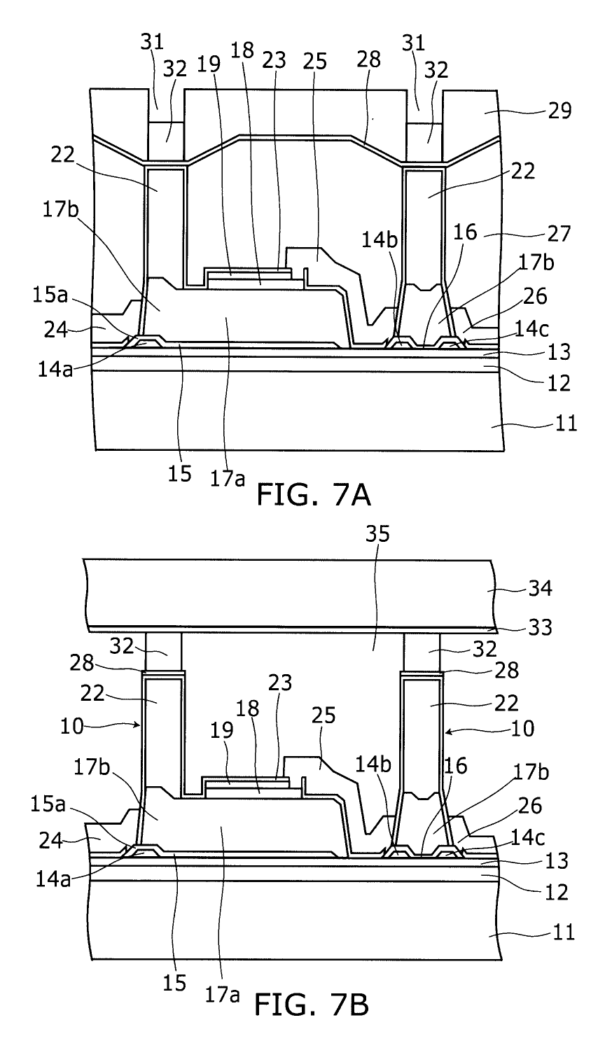

Then, as shown in FIG. 7A, an Au (gold) film 32, for example, is deposited to about 3 μm by electrolytic plating on the feeder metal film 28 exposed in the opening 31.

Then, after removing the plating resist 29, an etching mask is formed and patterned so as to cover the Au (gold) film 32. The etching mask is used to etch away the feeder metal film 28 and the protective resist layer 27.

Then, as shown in FIG. 7B, an upper sealing body 34 made of high-resistance silicon with Au/Sn film 33 on its one face is bonded onto the Au (gold) film 32. The Au (gold) film 32 and the Au/Sn film 33 are bonded to each other by metal diffusion bonding. Thus an upper hollow portion 35 defined by the sidewall 10 and the upper sealing body 34 is produced.

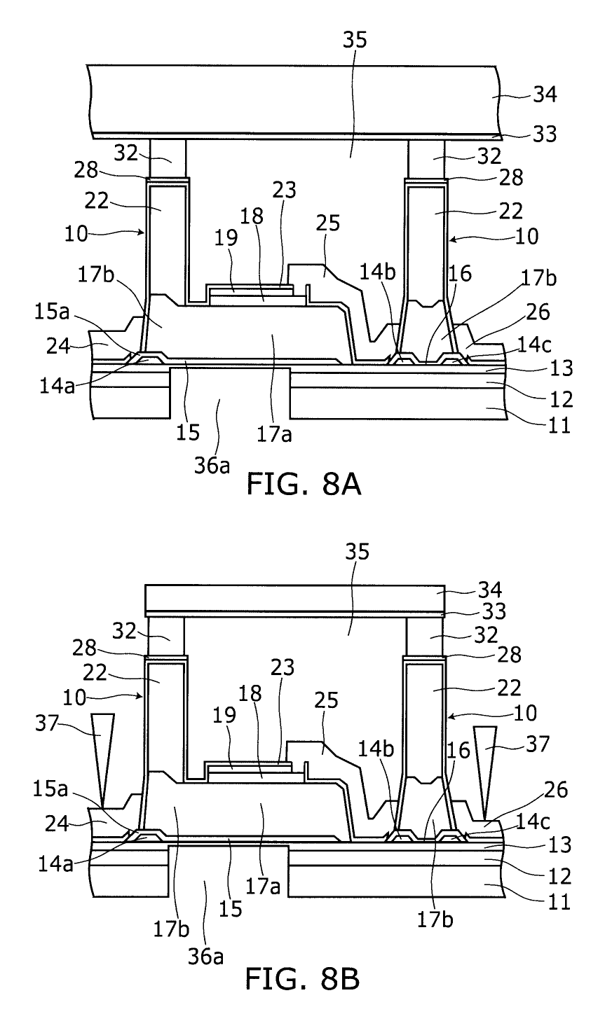

Next, as shown in FIG. 8A, the high-resistance silicon substrate 11 is thinned. Then the high-resistance silicon substrate 11 is subjected to high-rate RIE from backside. Furthermore, the thermal oxide film 12 is removed by wet etching with ammonium fluoride solution, for example. Thus a recess 36a is formed below the lower electrode 15. At this time, the silicon nitride film 13 serves as an etching stopper.

Next, as shown in FIG. 8B, the upper sealing body 34 is thinned. Then the upper sealing body 34 is diced with a blade, for example, to singulate the upper sealing body 34. While the lower extraction electrode 24 and the outer upper extraction electrode 26 exposed thereby are in contact with probes 37 to measure the filter resonance frequency, the deposit on the backside of the lower electrode 15 is etched (trimmed) or deposition onto the backside of the lower electrode 15 is performed to adjust the mass of the resonator portion, that is, to adjust the resonance frequency.

Then, as shown in FIG. 1, a lower sealing body 38 illustratively made of silicon is stuck via a metal film 39 to the backside of the high-resistance silicon substrate 11 to form a lower hollow portion 36 below the lower electrode 15. Then, upon singulation, a film bulk acoustic resonator shown in FIG. 1 is obtained. The metal film 39 is illustratively made of Ti/W/Au or Ti/Ni/Au.

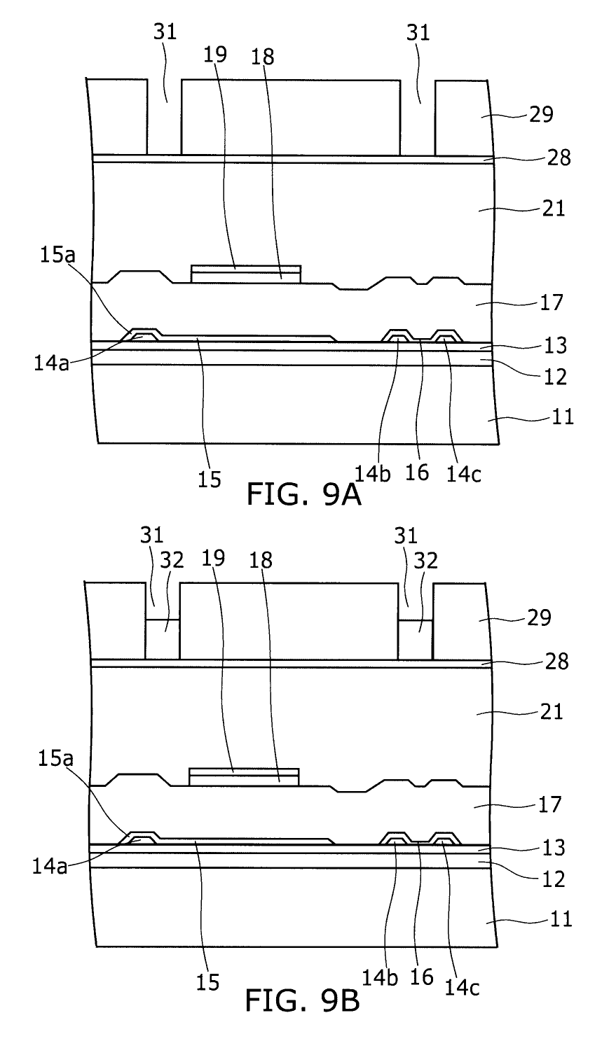

FIGS. 9 to 11 are schematic views illustrating another example process for manufacturing a film bulk acoustic resonator according to this embodiment.

In this example, after the process described above with reference to FIG. 3D, as shown in FIG. 9A, a feeder metal film 28 is formed on the silicon oxide film 21, a plating resist 29 is formed on the feeder metal film 28, and an opening 31 is formed in the plating resist 29.

Then, as shown in FIG. 9B, an Au (gold) film 32, for example, is deposited to about 3 μm by electrolytic plating on the feeder metal film 28 exposed in the opening 31.

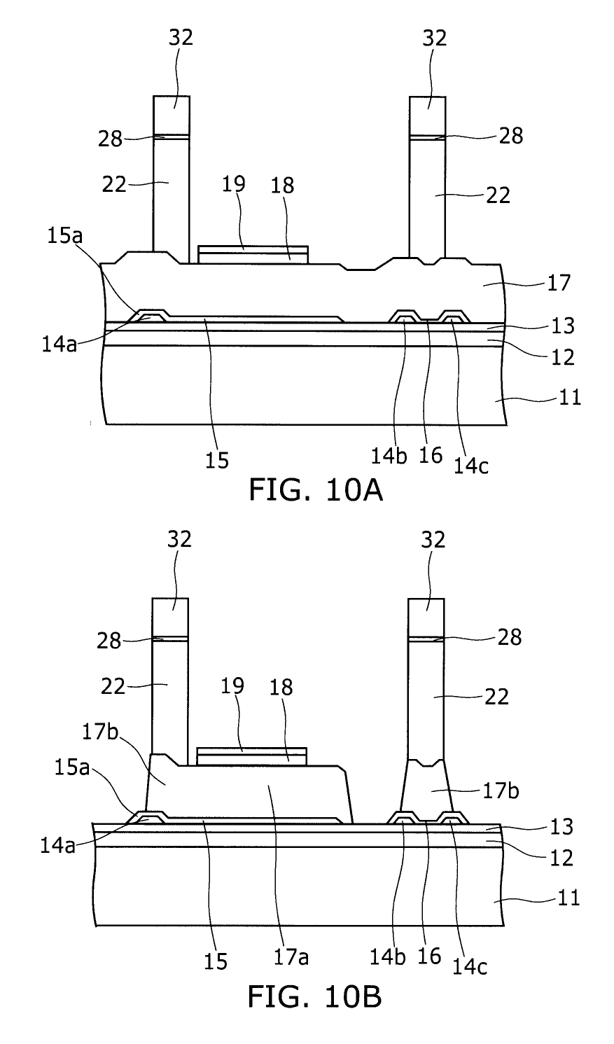

Next, after removing the resist 29, an etching mask is formed and patterned so as to cover the Au (gold) film 32, and is used to etch away the feeder metal film 28. Subsequently, the silicon oxide film 21 is selectively etched to form an insulator layer 22 surrounding the upper electrode 18 on all four sides as shown in FIG. 10A.

Next, as shown in FIG. 10B, the piezoelectric layer 17 is selectively etched. The piezoelectric layer 17 is left unremoved not only in the resonator portion (the portion sandwiched between the lower electrode 15 and the upper electrode 18) 17a, but also in the peripheral portion 17b surrounding the resonator portion 17a on all four sides.

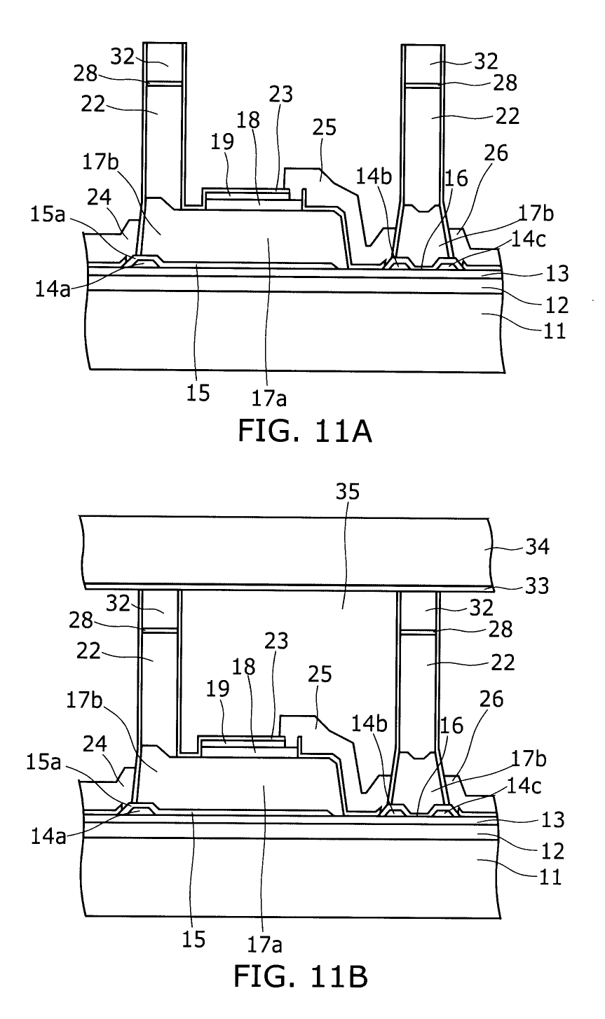

Next, as shown in FIG. 11A, a protective film 23 is formed to cover all the exposed surface of the structure produced by the foregoing processes. Then the protective film 23 is partially removed to expose part of the relay electrodes 15a, 16. In the relay electrode 15a, the portion outside the region surrounded by the insulator layer 22 and the piezoelectric layer peripheral portion 17b is exposed. In the relay electrode 16, the portion other than below the piezoelectric layer peripheral portion 17b, that is, the portion outside and inside the region surrounded by the insulator layer 22 and the piezoelectric layer peripheral portion 17b is exposed. Along with the protective film 23, the underlying mass addition film 19 is also partially removed, and the upper electrode 18 is also partially exposed. Furthermore, the upper face of the Au (gold) film 32 is also exposed.

Then a lower extraction electrode 24 is formed in contact with the exposed portion of the relay electrode 15a outside the region surrounded by the insulator layer 22 and the piezoelectric layer peripheral portion 17b. An inner upper extraction electrode 25 is formed in contact with the exposed portion of the upper electrode 18 and the exposed portion of the relay electrode 16 inside the region surrounded by the insulator layer 22 and the piezoelectric layer peripheral portion 17b. Furthermore, an outer upper extraction electrode 26 is formed in contact with the exposed portion of the relay electrode 16 outside the region surrounded by the insulator layer 22 and the piezoelectric layer peripheral portion 17b.

Next, as shown in FIG. 11B, an upper sealing body 34 made of high-resistance silicon with Au/Sn film 33 on its one face is bonded onto the Au (gold) film 32 to form an upper hollow portion 35.

Then, by the same processes as described above with reference to FIGS. 8A and 8B, a film bulk acoustic resonator shown in FIG. 1 is obtained.

### Second Embodiment

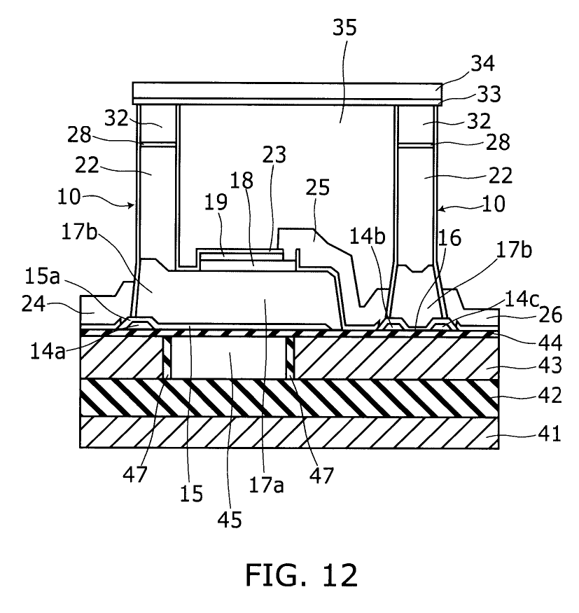

FIG. 12 is a schematic view illustrating the cross-sectional structure of the main part of a film bulk acoustic resonator according to a second embodiment of the invention.

The film bulk acoustic resonator according to this embodiment is different from that of the first embodiment in the method for forming the lower hollow portion.

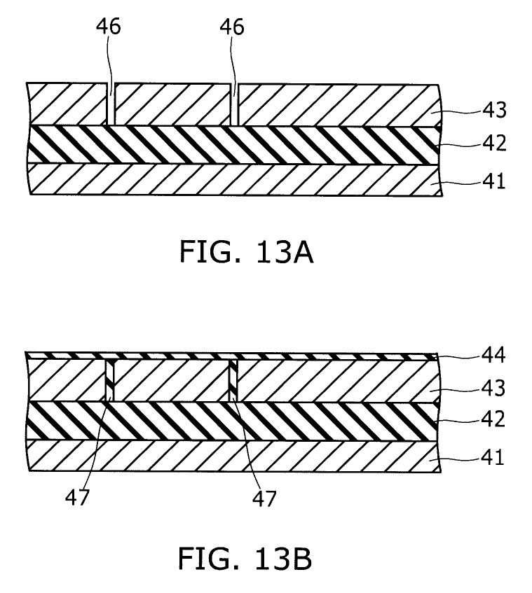

First, as shown in FIG. 13A, in an SOI (Silicon on Insulator) layer 43 formed on a silicon substrate 41 via a buried oxide film 42, a trench 46 reaching the buried oxide film 42 is formed. In forming the trench 46, for example, a laminated film of an SiN film of several hundred angstroms and a TEOS (tetraethoxysilane) film of several hundred nanometers was used as a mask.

Next, after cleaning, as shown in FIG. 13B, the trench is completely filled with TEOS film 47, and the TEOS film on the SOI layer 43 was removed by CMP. Then a thermal oxide film 44 of e.g. several hundred angstroms was formed.

Subsequently, on the thermal oxide film 44, the above-described processes from FIG. 3A onward are performed. Then, before the upper hollow portion 35 is sealed with the upper sealing body 34, the portion (sacrifice layer) of the SOI layer 43 surrounded by the oxide films 42, 47, and 44 is removed by dry etching with XeF₂ gas, for example, through the opening in the piezoelectric layer 17a to form a lower hollow portion 45 below the lower electrode 15 as shown in FIG. 12. Thus a film bulk acoustic resonator shown in FIG. 12 is obtained.

Also in this embodiment, as in the first embodiment, the piezoelectric layer originally serving as a resonator portion is also used as part of the sidewall 10 for forming the upper hollow portion 35. Thus the process for forming the resonator portion can be partially shared with the process for forming the sidewall. This can increase the process efficiency and achieve cost reduction.

The lower electrode 15 is connected to the relay electrode 15a provided below the piezoelectric layer peripheral portion 17b constituting part of the sidewall 10. The relay electrode 15a is connected to a lower extraction electrode 24 provided on the support body outside the sidewall 10. That is, the lower electrode 15 provided inside the sidewall 10 is extracted outside the sidewall 10 through the relay electrode 15a and the lower extraction electrode 24, and is connectable to an external circuit.

The upper electrode 18 is connected to the relay electrode 16 provided below the piezoelectric layer peripheral portion 17b through an inner upper extraction electrode 25. The relay electrode 16 is connected to an outer upper extraction electrode 26 provided on the support body outside the sidewall 10. That is, the upper electrode 18 provided inside the sidewall 10 is extracted outside the sidewall 10 through the inner upper extraction electrode 25, the relay electrode 16, and the outer upper extraction electrode 26, and is connectable to an external circuit.

The relay electrodes 15a, 16 for externally extracting the upper and lower electrode are patterned on the support body simultaneously with the formation of the lower electrode 15 before the piezoelectric layer 17a, 17b is formed. Thus the process for forming the resonator portion can be partially shared with the process for forming the external extraction electrodes. This can increase the process efficiency and achieve cost reduction. Furthermore, the external extraction structure can be formed by the known technique for patterning an interconnect on a semiconductor wafer without the process as in JP 2005-304021A where a via is formed in the wall of the upper hollow portion and filled with conductive material. This also contributes to reducing the process cost.

The piezoelectric layer peripheral portion 17b and the insulator layer 22 provided on the relay electrodes 15a, 16 are electrically insulative. Hence no short circuit occurs between the upper electrode 18 and the lower electrode 15. Furthermore, the insulator layer 22 illustratively made of silicon oxide, which has a smaller relative dielectric constant than materials commonly used for a piezoelectric layer (e.g. aluminum nitride), can be formed thicker than the piezoelectric layer peripheral portion 17b. Thus the increase of parasite capacitance between the bonding metal layers 32, 33 and the relay electrodes 15a, 16 can be reduced.

The material of the sidewall 10 is free from resin. The surface of the insulator layer 22 and the piezoelectric layer 17a, 17b facing the upper hollow portion 35 is covered with a protective film 23 illustratively made of silicon nitride. Hence no decomposition or shattering of resin components occurs in high-temperature, high-pressure, and high-humidity environments. Thus there is no decrease of the resonance frequency or degradation of resonance characteristics due to shattered material attached to the resonator portion, and a highly reliable hollow structure can be achieved.

1. A film bulk acoustic resonator comprising:
a support body having a lower hollow portion;
a lower electrode supported on the support body and provided above the lower hollow portion;
a piezoelectric layer provided on the lower electrode;
an upper electrode provided on the piezoelectric layer;
a sidewall surrounding the upper electrode, a portion of the sidewall being composed of the piezoelectric layer;
an upper sealing body bonded to an upper end of the sidewall and defining an upper hollow portion along with the sidewall; and
a relay electrode provided on the support body below the portion of the sidewall constituting the piezoelectric layer for extracting the lower electrode and the upper electrode onto the support body outside the sidewall.

2. The film bulk acoustic resonator according to claim 1, wherein the piezoelectric layer has a resonator portion sandwiched between the lower electrode and the upper electrode, and a peripheral portion constituting part of the sidewall and surrounding the resonator portion.

3. The film bulk acoustic resonator according to claim 2, wherein the peripheral portion is formed in the same process and made of the same material as the resonator portion.

4. The film bulk acoustic resonator according to claim 1, wherein the material of the sidewall is free from resin.

5. The film bulk acoustic resonator according to claim 1, wherein the sidewall includes the piezoelectric layer, an insulator layer, and a metal layer for bonding to the upper sealing body, provided sequentially from bottom.

6. The film bulk acoustic resonator according to claim 5, wherein the insulator layer is made of silicon oxide.

7. The film bulk acoustic resonator according to claim 5, wherein at least a portion of the piezoelectric layer and the insulator layer, the portion facing the upper hollow portion, is covered with a protective film made of insulating material.

8. The film bulk acoustic resonator according to claim 7, wherein the protective film is made of silicon nitride.

9. The film bulk acoustic resonator according to claim 1, further comprising:
a foundation electrode provided below the relay electrode, the foundation electrode having a higher etching selection ratio relative to the piezoelectric layer than the relay electrode.

10. The film bulk acoustic resonator according to claim 9, wherein the foundation electrode is formed in a striped configuration, both longitudinal edges of the foundation electrode are tapered.

11. The film bulk acoustic resonator according to claim 1, wherein the lower electrode is connected to a part of the relay electrode, the relay electrode is connected to a lower extraction electrode provided on the support body outside the sidewall.

12. The film bulk acoustic resonator according to claim 1, wherein the upper electrode is connected to the relay electrode through an inner upper extraction electrode, the relay electrode is connected to an outer upper extraction electrode provided on the support body outside the sidewall.

13. A method for manufacturing a film bulk acoustic resonator comprising:
forming a lower electrode and a relay electrode on a support body;
forming a piezoelectric layer so as to cover the lower electrode and the relay electrode;
forming an upper electrode on the piezoelectric layer;
forming a sidewall surrounding the upper electrode, a portion of the sidewall being composed of the piezoelectric layer;
forming an extraction electrode provided in contact with the relay electrode for extracting the lower electrode and the upper electrode onto the support body outside the sidewall;
bonding an upper sealing body to an upper end of the sidewall, the upper sealing body defining an upper hollow portion along with the sidewall; and
forming a lower hollow portion below the lower electrode.

14. The method for manufacturing a film bulk acoustic resonator according to claim 13, wherein the lower electrode and the relay electrode are simultaneously formed.

15. The method for manufacturing a film bulk acoustic resonator according to claim 13, further comprising forming an insulator layer on a peripheral portion of the piezoelectric layer, the peripheral portion constituting part of the sidewall.

16. The method for manufacturing a film bulk acoustic resonator according to claim 15, wherein the insulator layer is made of silicon oxide.

17. The method for manufacturing a film bulk acoustic resonator according to claim 15, further comprising covering at least a portion of the piezoelectric layer and the insulator layer, the portion facing the upper hollow portion, with a protective film made of insulating material.

18. The method for manufacturing a film bulk acoustic resonator according to claim 15, further comprising forming a metal layer for bonding to the upper sealing body on the insulator layer.

19. The method for manufacturing a film bulk acoustic resonator according to claim 13, further comprising forming a foundation electrode below the relay electrode, the foundation electrode having a higher etching selection ratio relative to the piezoelectric layer than the relay electrode.

20. The method for manufacturing a film bulk acoustic resonator according to claim 19, wherein the foundation electrode is formed in a striped configuration, both longitudinal edges of the foundation electrode are tapered.
